(19) United States
(12) Patent Application Publication
(10) Pub. No.: US 2024/0006839 A1
(43) Pub. Date: Jan. 4, 2024

(54) SEMICONDUCTOR DEVICE

(71) Applicant: Mitsubishi Electric Corporation, Tokyo (JP)

(72) Inventors: Akio SHIRASAKI, Tokyo (JP); Naoki KOSAKA, Tokyo (JP); Masaaki SHIMADA, Tokyo (JP); Tadayoshi HATA, Tokyo (JP); Nao HIROSHIGE, Tokyo (JP)

(73) Assignee: Mitsubishi Electric Corporation, Tokyo (JP)

(21) Appl. No.: 18/255,758

(22) PCT Filed: Jan. 28, 2021
(86) PCT No.: PCT/JP2021/003036

§ 371 Date: Jun. 2, 2023

(51) Int. Cl. H01S 5/02212; H01S 5/024

(52) U.S. Cl. CPC H01S 5/02212; H01S 5/02469

(57) ABSTRACT

A semiconductor device according to the present disclosure includes a base body having a first face and a second face, a lead passing through a through hole penetrating the base body and extending to a side of the first face, a sealing body filling the through hole, a dielectric substrate having a first main surface and a second main surface erected with respect to the first face, a semiconductor laser provided on a side of the first main surface of the dielectric substrate, a signal line provided on the first main surface and electrically connected to the semiconductor laser, a connecting member electrically connecting the signal line and the lead to each other, and a rear surface conductor provided on the second main surface, wherein the sealing body is provided directly below the rear surface conductor as viewed from a direction perpendicular to the first face.

### FIELD

The present disclosure relates to a semiconductor device.

### BACKGROUND

PTL 1 discloses a package for mounting an electronic component. The package includes a base body made of a metal plate-like member and having a through hole penetrating in a thickness direction. The base body has one main surface on which an electronic component is mounted and a thin layer portion which is thinner than another portion with respect to the one main surface. A signal line conductor which extends in a direction orthogonal to a main surface of the base body is inserted into a center of the through hole. A dielectric is provided between the signal line conductor and an inner peripheral surface of the through hole. A connecting conductor which connects the electronic component and the signal line conductor to each other is provided on a side of the one main surface of the base body. A ground conductor which extends in parallel with the signal line conductor is provided on a side of the other main surface of the base body. A portion of the signal line conductor which protrudes on the side of the one main surface of the base body and the connecting conductor are connected to each other by a conductive material such as a brazing filler metal.

### CITATION LIST

### Patent Literature

[PTL 1] JP 2012-064817 A

### SUMMARY

### Technical Problem

In PTL 1, when a distance between the signal line which is a connecting conductor and a lead pin which is a signal line conductor increases, a metal bonding material which bonds the signal line and the lead pin to each other becomes thicker. Accordingly, an inductance component of the metal bonding material increases. At this point, when a semiconductor laser is to be mounted as the electronic component, there is a possibility that an increase in transmission loss or the like due to a decline in frequency characteristics may occur. Therefore, a deterioration of quality of electric signals to be transmitted to the semiconductor laser may occur.

An object of the present disclosure is to obtain a semiconductor device capable of suppressing a deterioration of quality of electric signals.

### Solution to Problem

A semiconductor device according to the present disclosure includes a base body which has a first face and a second face on an opposite side to the first face and in which a through hole penetrating from the first face to the second face is formed, a lead which passes through the through hole and which extends to a side of the first face of the base body, a sealing body which fills a space between the lead and a side surface of the base body forming the through hole, a dielectric substrate which has a first main surface being provided in a state of being erected with respect to the first face of the base body and a second main surface being a face on an opposite side to the first main surface and being provided in a state of being erected with respect to the first face of the base body, a semiconductor laser which is provided on a side of the first main surface of the dielectric substrate, a signal line which is provided on the first main surface of the dielectric substrate and which is electrically connected to the semiconductor laser, a connecting member which electrically connects the signal line and the lead to each other, and a rear surface conductor which is provided on the second main surface of the dielectric substrate, wherein the sealing body is provided directly below the rear surface conductor as viewed from a direction perpendicular to the first face.

### Advantageous Effects of Invention

In the semiconductor device according to the present disclosure, the sealing body is inserted to directly below the rear surface conductor. As a result, the connecting member can be shortened and an inductance component of the connecting member can be suppressed. Therefore, a deterioration of quality of electric signals to be transmitted to the semiconductor laser can be suppressed.

### BRIEF DESCRIPTION OF DRAWINGS

FIG. 1 is a plan view of a semiconductor device according to a first embodiment.

FIG. 2 is a sectional view obtained by cutting FIG. 1 along a straight line A-A.

FIG. 3 is a plan view of a semiconductor device according to a first comparative example of the first embodiment.

FIG. 4 is a sectional view obtained by cutting FIG. 3 along a straight line A-A.

FIG. 5 is a plan view of a semiconductor device according to a second comparative example of the first embodiment.

FIG. 6 is a sectional view obtained by cutting FIG. 5 along a straight line A-A.

FIG. 7 is a plan view of a semiconductor device according to a modification of the first embodiment.

FIG. 8 is a sectional view of a semiconductor device according to a second embodiment.

FIG. 9 is a sectional view obtained by cutting FIG. 8 along a straight line B-B.

FIG. 10 is an enlarged view of a portion enclosed by a dashed line in FIG. 9.

FIG. 11 is a sectional view of a semiconductor device according to a third embodiment.

FIG. 12 is a sectional view obtained by cutting FIG. 11 along a straight line B-B.

FIG. 13 is an enlarged view of a portion enclosed by a dashed line in FIG. 12.

FIG. 14 is a sectional view of a semiconductor device according to a fourth embodiment.

FIG. 15 is a sectional view obtained by cutting FIG. 14 along a straight line B-B.

FIG. 16 is an enlarged view of a portion enclosed by a dashed line in FIG. 15.

FIG. 17 is a plan view of a semiconductor device according to a sixth embodiment.

FIG. 18 is a sectional view of the semiconductor device according to the sixth embodiment.

FIG. 19 is a sectional view showing a state where a cap has been attached to the semiconductor device according to the sixth embodiment.

FIG. 20 is a perspective view of a measurement system according to a seventh embodiment.

FIG. 21 is a plan view of a semiconductor device according to a comparative example of the seventh embodiment.

FIG. 22 is a perspective view showing a state where the semiconductor device according to the comparative example has been attached to the energizing jig.

FIG. 23 is a perspective view showing a state where the semiconductor device according to the sixth embodiment has been attached to the energizing jig.

### DESCRIPTION OF EMBODIMENTS

A semiconductor device according to each embodiment is described with reference to drawings. Identical or corresponding constitutional elements are given the same reference numerals, and the repeated description of such constitutional elements may be omitted.

### First Embodiment

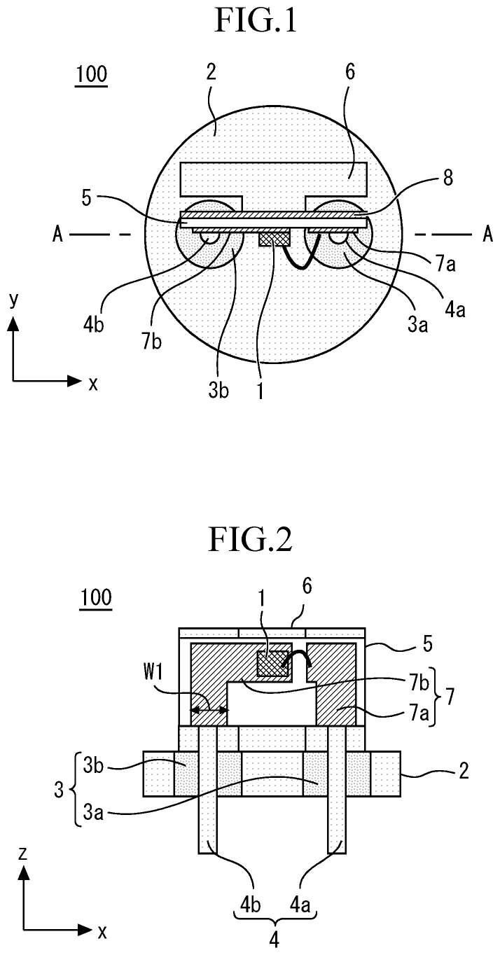

FIG. 1 is a plan view of a semiconductor device 100 according to a first embodiment. FIG. 2 is a sectional view obtained by cutting FIG. 1 along a straight line A-A. For example, the semiconductor device 100 is a package for a semiconductor laser such as a 25 Gbps TO-CAN (Transistor Outline-CAN) package.

The semiconductor device 100 includes a base body 2. The base body 2 has a first face and a second face on an opposite side to the first face. An electronic component such as a semiconductor laser 1 is provided on a side of the first face of the base body 2. A pair of though holes which penetrates from the first face to the second face is formed in the base body 2. The base body 2 is also referred to as an eyelet.

The semiconductor device 100 includes leads 4a and 4b which form a pair of leads 4. The lead 4 is also referred to as a lead pin. The leads 4a and 4b respectively pass through the pair of through holes formed in the base body 2 and extend to the side of the first face of the base body 2. The through holes of the base body 2 are provided with sealing bodies 3a and 3b which form a pair of sealing bodies 3. The sealing bodies 3a and 3b fill spaces between the leads 4a and 4b and side surfaces of the base body 2 which form the through holes. For example, the sealing bodies 3a and 3b are made of sealing glass.

A conductor block 6 is provided on the first face of the base body 2. The conductor block 6 is formed of metal. The conductor block 6 holds a dielectric substrate 5 via a rear surface conductor 8 on the side of the first face of the base body 2.

The dielectric substrate 5 has a first main surface and a second main surface which are provided in a state of being erected with respect to the first face of the base body 2. The second main surface is a face on an opposite side to the first main surface. The dielectric substrate 5 is also referred to as a submount. The semiconductor laser 1 is provided on a side of the first main surface of the dielectric substrate 5. Signal lines 7a and 7b which form a pair of signal lines 7 electrically connected to the semiconductor laser 1 are provided on the first main surface of the dielectric substrate 5. In the example shown in FIG. 2, the semiconductor laser 1 is provided on the signal line 7b and connected by a wire to the signal line 7a. The signal lines 7a and 7b and the leads 4a and 4b are respectively electrically connected by connecting members to be described later. The rear surface conductor 8 is provided on the second main surface of the dielectric substrate 5.

The conductor block 6 has a T-shape in a plan view. Among the conductor block 6, only a portion of a side which opposes the rear surface conductor 8 is in contact with the rear surface conductor 8. Specifically, among the rear surface conductor 8, only a center which overlaps with the semiconductor laser 1 is fixed to the conductor block 6. Among the rear surface conductor 8, vicinities of both ends which overlap with the leads 4a and 4b are not fixed to the conductor block 6. In other words, the rear surface conductor 8 has a portion in contact with the conductor block 6 in a portion which overlaps with the semiconductor laser 1 as viewed from a direction perpendicular to the first main surface of the dielectric substrate 5. In addition, the rear surface conductor 8 has a separated portion which is separated from the conductor block 6 on both sides of the portion in contact with the conductor block 6 in a direction along the first face of the base body 2. In this case, the direction perpendicular to the first main surface of the dielectric substrate 5 is a y-axis direction in FIG. 1. In addition, the direction along the first face of the base body 2 in the rear surface conductor 8 is an x-axis direction in FIG. 1.

The sealing body 3 is provided directly below the rear surface conductor 8 as viewed from a direction perpendicular to the first face of the base body 2. In particular, the sealing body 3 is provided in a region on an opposite side to the dielectric substrate 5 with respect to the rear surface conductor 8 as viewed from the direction perpendicular to the first face of the base body 2. In other words, the sealing body 3 protrudes between the separated portion from the conductor block 6 among the rear surface conductor 8 and the conductor block 6 as viewed from the direction perpendicular to the first face of the base body 2. The sealing body 3 is inserted further toward a side of the conductor block 6 than a face where the rear surface conductor 8 and the conductor block 6 come into contact with each other in the y-axis direction.

In the semiconductor device 100, the lead 4 is fixed to the base body 2 by a glass hermetic technique using the sealing body 3. The lead 4 is fixed to a center of the through hole formed in the base body 2. The conductor block 6 and the base body 2 may be formed of a same metal. Shapes of the conductor block 6 and the base body 2 are formed by press molding, machining, or the like. The rear surface conductor 8 and the conductor block 6 are fixed by a bonding material such as a solder. In addition, the semiconductor laser 1 is fixed to the side of the first main surface of the dielectric substrate 5 by a bonding material such as a solder. For example, the dielectric substrate 5 has a coefficient of thermal expansion which is in between those of the semiconductor laser 1 and the conductor block 6. The dielectric substrate 5 is formed of ceramic. The dielectric substrate 5 suppresses breakage of the semiconductor laser 1 due to thermal stress attributable to a mismatch of coefficients of thermal expansion between the semiconductor laser 1 and the conductor block 6.

A differential signal is input to the leads 4a and 4b from outside. The signal lines 7a and 7b transmit the differential signal from the leads 4a and 4b to an anode electrode and a cathode electrode of the semiconductor laser 1. In the semiconductor device 100, the signal lines 7a and 7b and the rear surface conductor 8 sandwich the dielectric substrate 5. Accordingly, a microstrip line is formed. Characteristic impedance of the signal lines 7a and 7b is adjusted to an optimal value so that an electric signal input to the leads 4a and 4b is transmitted to the semiconductor laser 1 with lowest loss. Note that the leads 4a and 4b and the signal lines 7a and 7b are electrically connected to each other using a metal bonding material such as a solder, a metal wire, or the like as a connecting member.

In a mobile network which supports a mobile phone service or the like, an optical line connecting a primary station which performs digital signal processing and a secondary station which performs wireless signal transmission/reception to each other is referred to as a mobile fronthaul. In recent years, signal transmission rates of a mobile fronthaul have reached 25 Gbps and demands for a semiconductor laser capable of operating at high speed are increasing. In a mobile fronthaul, TO-CAN is a dominant package form of a semiconductor laser.

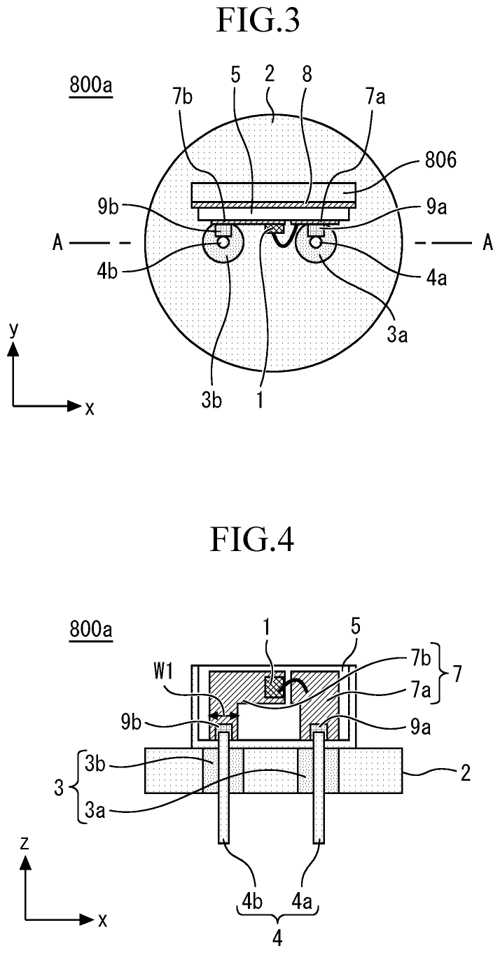

FIG. 3 is a plan view of a semiconductor device 800a according to a first comparative example of the first embodiment. FIG. 4 is a sectional view obtained by cutting FIG. 3 along a straight line A-A. The semiconductor device 800a differs from the semiconductor device 100 in that the sealing body 3 is not inserted to directly below the rear surface conductor 8. In addition, the semiconductor device 800a has a conductor block 806 with a flat plate shape. The signal lines 7a and 7b and the leads 4a and 4b are respectively electrically connected to each other via bonding materials 9a and 9b.

In such a structure, when distances between the signal lines 7a and 7b and the leads 4a and 4b are long, the bonding materials 9a and 9b become thicker in the y-axis direction. Accordingly, an inductance component of the bonding materials 9a and 9b increases. Therefore, a deterioration of quality of electric signals to be transmitted to the semiconductor laser 1 may possibly occur. An example of the deterioration of quality is an increase in transmission loss due to a decline in frequency characteristics.

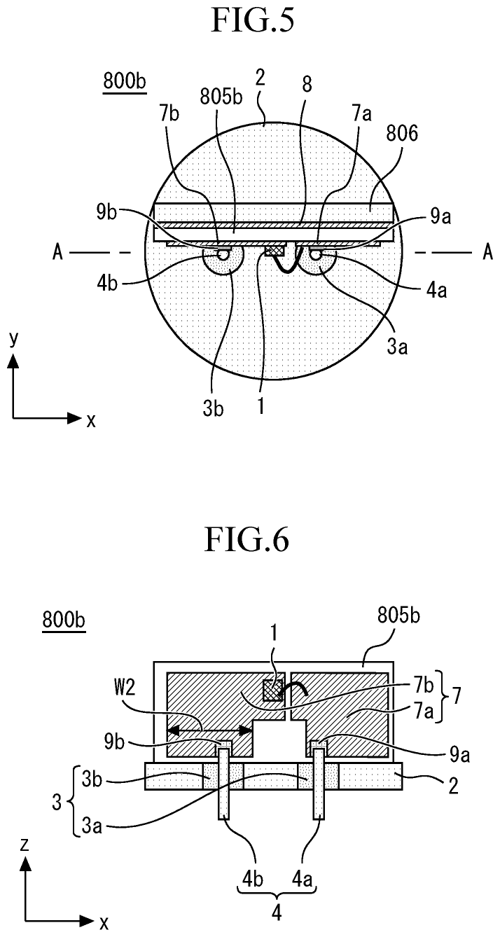

FIG. 5 is a plan view of a semiconductor device 800b according to a second comparative example of the first embodiment. FIG. 6 is a sectional view obtained by cutting FIG. 5 along a straight line A-A. In the semiconductor device 800b, a dielectric substrate 805b is thicker than in the semiconductor device 800a. In this manner, by making the dielectric substrate 805b thicker, distances between the signal lines 7a and 7b and the leads 4a and 4b can be reduced. Accordingly, the bonding materials 9a and 9b can be made thinner in the y-axis direction and an inductance component of the bonding materials 9a and 9b can be reduced.

However, in a microstrip line, characteristic impedance increases as a dielectric substrate becomes thicker. In addition, characteristic impedance decreases as a line width of signal lines on a front surface side increases. Therefore, in the semiconductor device 800b, in order to adjust the characteristic impedance of the signal lines 7a and 7b to a same value as in the semiconductor device 800a, a line width W2 of the signal lines 7a and 7b of the semiconductor device 800b is increased as compared to a line width W1 of the signal lines 7a and 7b of the semiconductor device 800a. As a result, an area of the dielectric substrate 805b increases and package size becomes larger.

In contrast, in the semiconductor device 100 according to the present embodiment, the sealing body 3 is inserted to directly below the rear surface conductor 8. Therefore, in the semiconductor device 100, the distance between the lead 4 and the signal line 7 can be reduced while keeping the dielectric substrate 5 thin as compared to the semiconductor devices 800a and 800b. As a result, the bonding materials 9a and 9b can be made thin and an inductance component of the bonding materials 9a and 9b can be suppressed. Therefore, a deterioration of quality of electric signals to be transmitted to a semiconductor laser can be suppressed and the semiconductor device 100 with superior high-frequency characteristics can be obtained.

In addition, in the semiconductor device 100, since the dielectric substrate 5 is thin, the line width W1 of the signal lines 7a and 7b necessary for obtaining optimal characteristic impedance is smaller than the line width W2 of the semiconductor device 800b. Therefore, in the semiconductor device 100, an area of the dielectric substrate 5 can be reduced as compared to the semiconductor device 800b. Accordingly, the dielectric substrate 5 can be manufactured at a low cost. In addition, the package can be downsized. In the present embodiment, the distance between the lead 4 and the signal line 7 can be reduced while suppressing an increase in size of the dielectric substrate 5.

Moreover, in the present embodiment, since the dielectric substrate 5 is thin, thermal resistance between the semiconductor laser 1 and the conductor block 6 can be reduced. Therefore, thermal dissipation of the semiconductor laser 1 can be improved and an improvement in light emission efficiency and a prolongation of a lifetime of the semiconductor laser 1 can be realized.

Furthermore, in the present embodiment, since thermal dissipation of the semiconductor laser 1 can be improved, sufficient thermal dissipation can be secured even when a separated portion with the conductor block 6 is provided on the rear surface conductor 8. In the present embodiment, among the rear surface conductor 8, vicinities of both ends in the x-axis direction are not fixed to the conductor block 6. Accordingly, a bonding area between the dielectric substrate 5 and the conductor block 6 can be reduced. Therefore, thermal stress applied to the dielectric substrate 5 by the conductor block 6 can be reduced and reliability of the semiconductor device 100 can be improved.

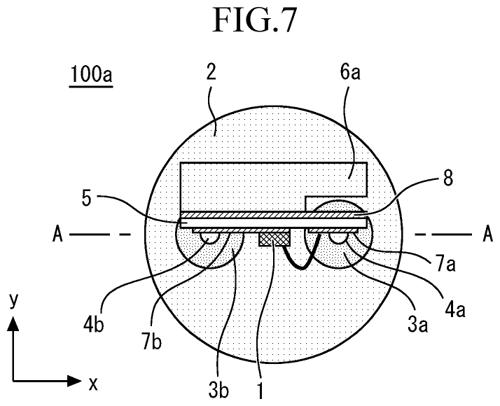

FIG. 7 is a plan view of a semiconductor device 100a according to a modification of the first embodiment. As a modification of the present embodiment, the rear surface conductor 8 may have a separated portion which is separated from a conductor block 6a on at least one side of a portion which overlaps with the semiconductor laser 1 as viewed from the direction perpendicular to the first main surface of the dielectric substrate 5. In addition, an entire surface of the rear surface conductor 8 may be fixed to the conductor block 6.

Furthermore, in the present embodiment, the sealing body 3 protrudes between the separated portion from the conductor block 6 among the rear surface conductor 8 and the conductor block 6 as viewed from the direction perpendicular to the first face of the base body 2. The sealing body 3 is not limited to such a configuration and need only be provided directly below the rear surface conductor 8 as viewed from the direction perpendicular to the first face of the base body 2.

In addition, the conductor block 6 and the dielectric substrate 5 according to the present embodiment are erected with respect to the base body 2. The conductor block 6 and the dielectric substrate 5 are not limited to such a configuration and may be inclined with respect to the first face of the base body 2. Accordingly, an emission direction of laser light of the semiconductor device 100 can be adjusted to a desired angle. For example, when laser light emitted by the semiconductor device 100 impinges on some kind of reflecting body, reflected light may return to the semiconductor laser 1. Since the reflected return light inhibits stable operations of the semiconductor laser 1, the reflected return light is desirably reduced. In consideration thereof, by adjusting an angle formed between the conductor block 6 and the dielectric substrate 5 and the first face of the base body 2 to an angle which minimizes reflected return light instead of a right angle, the operation of the semiconductor laser 1 can be stabilized.

Furthermore, the semiconductor laser 1 may be driven by a single-ended signal instead of a differential signal. In this case, there may be one signal line 7 and one lead 4.

These modifications can be applied, as appropriate, to semiconductor devices according to the following embodiments. Note that the semiconductor devices according to the following embodiments are similar to that of the first embodiment in many respects, and thus differences between the semiconductor devices according to the following embodiments and that of the first embodiment will be mainly described below.

### Second Embodiment

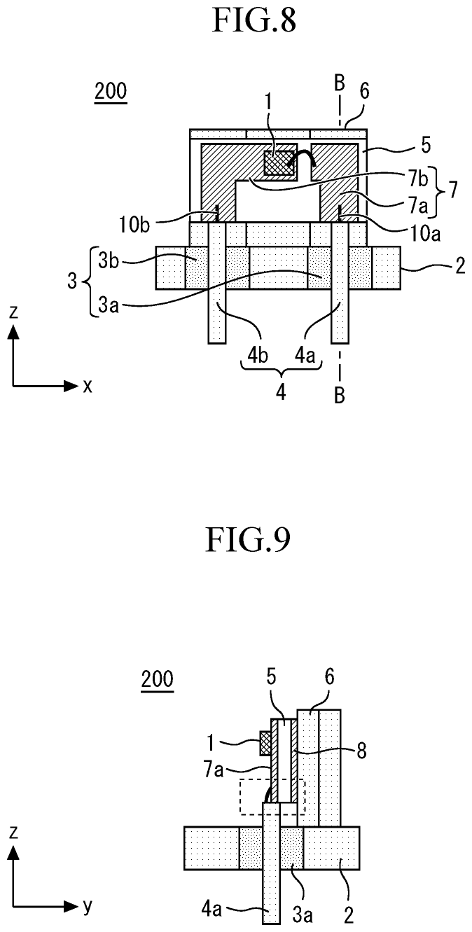

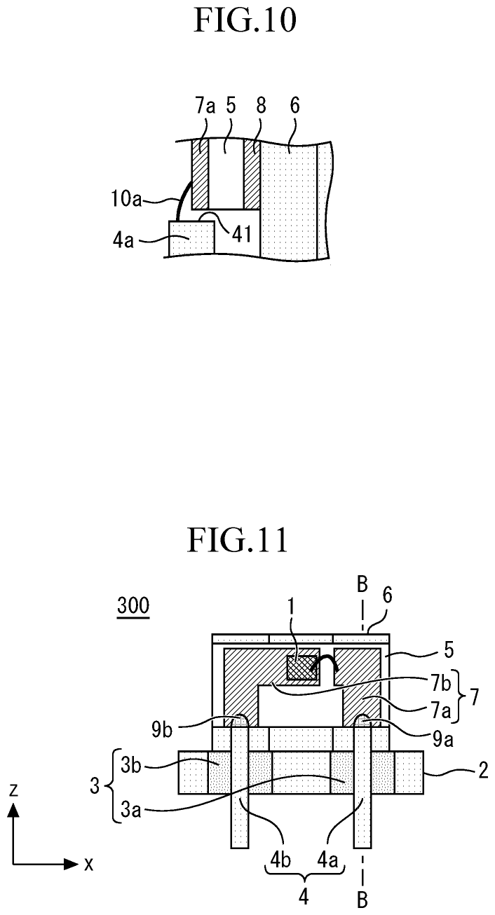

FIG. 8 is a sectional view of a semiconductor device 200 according to a second embodiment. FIG. 9 is a sectional view obtained by cutting FIG. 8 along a straight line B-B. FIG. 10 is an enlarged view of a portion enclosed by a dashed line in FIG. 9. In the semiconductor device 200, connecting members which electrically connect the leads 4a and 4b and the signal lines 7a and 7b to each other are wires 10a and 10b. The wires 10a and 10b are formed of metal. In the present embodiment, the wires 10a and 10b can be shortened by reducing a distance between the lead 4 and the signal line 7. As a result, an inductance component of the wires 10a and 10b can be suppressed.

In addition, in the direction perpendicular to the first face of the base body 2, a distance between the first face of the base body 2 and the dielectric substrate 5 is larger than a distance between the first face of the base body 2 and an end on a side of the dielectric substrate 5 of the lead 4. In other words, lower ends of the dielectric substrate 5 and the signal line 7 are provided at positions higher than an upper end face 41 of the lead 4. The wires 10a and 10b electrically connect the upper end faces 41 of the leads 4a and 4b and the signal lines 7a and 7b to each other.

In the semiconductor devices 800a and 800b according to the comparative examples, the signal line 7, the dielectric substrate 5, and the rear surface conductor 8 are inserted between the lead 4 and the conductor block 6. With this structure, due to variability in a fixing position of the lead 4 with respect to the base body 2, there is a possibility that the signal line 7, the dielectric substrate 5, and the rear surface conductor 8 cannot be inserted between the lead 4 and the conductor block 6.

In contrast, in the present embodiment, there is no need to insert the signal line 7, the dielectric substrate 5, and the rear surface conductor 8 between the lead 4 and the conductor block 6. Therefore, the inconvenience described above never occurs.

In addition, generally, the wires 10a and 10b more readily deform than the signal line 7 and the lead 4. Therefore, stress generated on the dielectric substrate 5 can be reduced and product reliability can be improved.

Furthermore, the lead 4a and the signal line 7a as well as the lead 4b and the signal line 7b are respectively connected to each other by single wires. However, the connections are not limited thereto and the lead 4 and the signal line 7 may be connected to each other by two or more wires. Accordingly, an inductance component due to the wires can be reduced. Therefore, a quality of electric signals to be transmitted to the semiconductor laser 1 can be improved.

### Third Embodiment

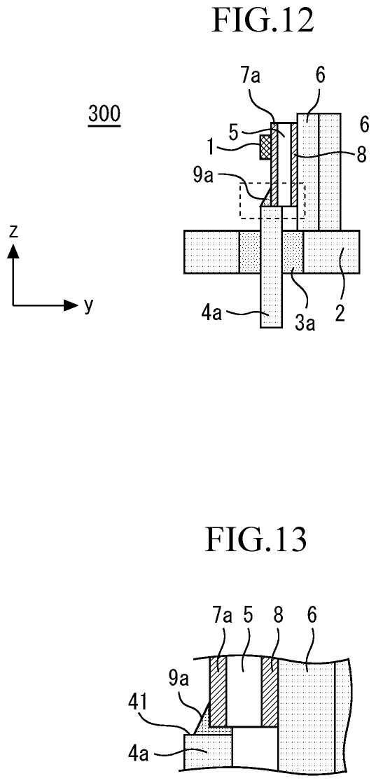

FIG. 11 is a sectional view of a semiconductor device 300 according to a third embodiment. FIG. 12 is a sectional view obtained by cutting FIG. 11 along a straight line B-B. FIG. 13 is an enlarged view of a portion enclosed by a dashed line in FIG. 12. In the semiconductor device 300, connecting members which electrically connect the leads 4a and 4b and the signal lines 7a and 7b to each other are the bonding materials 9a and 9b. For example, the bonding materials 9a and 9b are metal bonding materials such as a solder. In addition, a lower ends of the dielectric substrate 5 and the signal line 7 are provided at positions higher than the upper end face 41 of the lead 4. The bonding materials 9a and 9b electrically connect the upper end faces 41 of the leads 4a and 4b and the signal lines 7a and 7b to each other.

Even in the present embodiment, there is no need to insert the signal line 7, the dielectric substrate 5, and the rear surface conductor 8 between the lead 4 and the conductor block 6 in a similar manner to the second embodiment. In addition, by using the bonding materials 9a and 9b as connecting members, an inductance component can be reduced as compared to a case where the wires 10a and 10b are used as connecting members. Therefore, a quality of electric signals to be transmitted to the semiconductor laser 1 can be improved.

### Fourth Embodiment

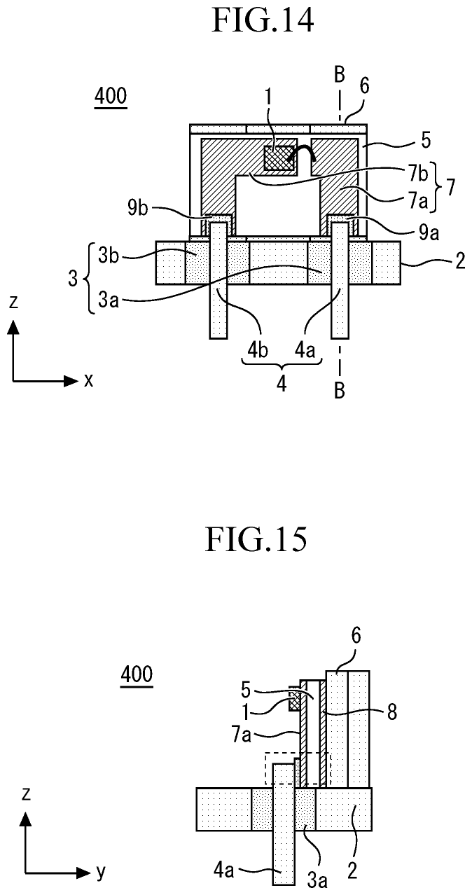

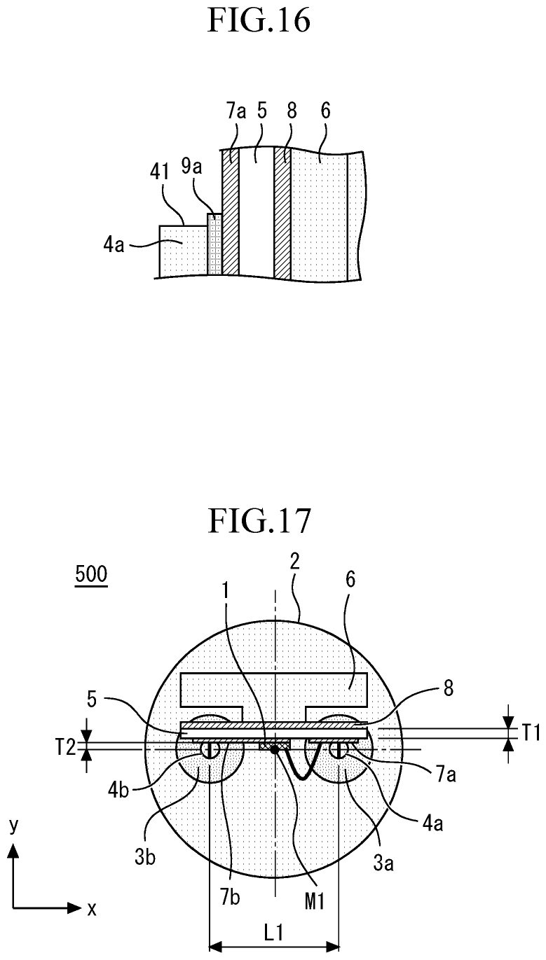

FIG. 14 is a sectional view of a semiconductor device 400 according to a fourth embodiment. FIG. 15 is a sectional view obtained by cutting FIG. 14 along a straight line B-B. FIG. 16 is an enlarged view of a portion enclosed by a dashed line in FIG. 15. In the semiconductor device 400, the lead 4 and the signal line 7 oppose each other in the direction perpendicular to the first main surface of the dielectric substrate 5. A portion which opposes the signal line 7 among the lead 4 and the signal line 7 are electrically connected to each other by bonding materials 9a and 9b.

In the present embodiment, the dielectric substrate 5 can be made thinner than in the semiconductor devices 200 and 300 according to the second and third embodiments. Therefore, an area of the dielectric substrate 5 can be reduced.

### Fifth Embodiment

For example, the dielectric substrate 5 is formed of alumina (Al₂O₃), aluminum nitride (AlN), or silicon carbide (SiC). Thermal conductivity decreases in an order of SiC, MN, and Al₂O₃. In addition, a rate of thermal expansion increases in an order of SiC, MN, and Al₂O₃.

For example, the conductor block 6 is formed of SPCC (Steel Plate Cold Commercial), Kovar, or copper-tungsten. Examples of copper-tungsten include CuW (10/90) and CuW (20/80). Thermal conductivity decreases in an order of CuW (20/80), CuW (10/90), SPCC, and Kovar. A rate of thermal expansion increases in an order of Kovar, CuW (10/90), CuW (20/80), and SPCC.

Materials of the dielectric substrate 5 and the conductor block 6 can be appropriately combined within a range in which the semiconductor laser 1 and the dielectric substrate 5 do not break due to thermal stress. In the semiconductor devices 300 and 400 according to the third and fourth embodiments, the bonding materials 9a and 9b are used to electrically connect the signal line 7 and the lead 4 to each other. Therefore, there is a possibility that a relatively large thermal stress may be applied to the dielectric substrate 5. Accordingly, the rates of thermal expansion of the dielectric substrate 5 and the conductor block 6 are desirably matched with each other.

When using Al₂O₃ as the material of the dielectric substrate 5, for example, CuW (10/90) is desirably used as the material of the conductor block 6. The rate of thermal expansion of Al₂O₃ is 6.9 to 7.2 ppm/K and the rate of thermal expansion of CuW (10/90) is 7 ppm/K. When using MN as the material of the dielectric substrate 5, Kovar is desirably used as the material of the conductor block 6. The rate of thermal expansion of AlN is 4.6 ppm/K and the rate of thermal expansion of Kovar is 5.1 ppm/K.

When the wires 10a and 10b are used to electrically connect the signal line 7 and the lead 4 to each other as in the semiconductor device 200 according to the second embodiment, the thermal stress applied to the dielectric substrate 5 is relatively small. Therefore, selecting a material with high thermal conductivity may be prioritized over matching the rates of thermal expansion of the dielectric substrate 5 and the conductor block 6 with each other. Accordingly, thermal dissipation of the semiconductor laser 1 can be improved. For example, preferably, MN is used as the material of the dielectric substrate 5 and CuW (20/80) is used as the material of the conductor block 6. The thermal conductivity of AlN is 170 to 200 W/m·K and the thermal conductivity of CuW (20/80) is 200 W/m·K.

The base body 2 and the conductor block 6 may be formed of SPCC or Kovar and may be integrated. Generally, SPCC or Kovar is often used as the material of the base body 2. Therefore, by selecting SPCC or Kovar as the material of the conductor block 6, the base body 2 and the conductor block 6 can be integrated. In this case, shapes of the base body 2 and the conductor block 6 can be collectively formed by a method such as press molding or machining.

AlN may be used as the material of the dielectric substrate 5 and SPCC may be used as the material of the conductor block 6. The rate of thermal expansion of SPCC is 73.3 W/m·K. Accordingly, the base body 2 and the conductor block 6 can be integrated to increase productivity while improving thermal dissipation of the semiconductor laser 1.

SiC, Al₂O₃, and AlN having been cited as examples of the material of the dielectric substrate 5 have relative permittivities which descend in this order. The larger the relative permittivity, the smaller an impedance of the signal line 7. Therefore, when adjusting the characteristic impedance of the signal line 7 to an optimal value determined in advance, Al₂O₃ or SiC with high relative permittivity is preferably used. Accordingly, a line width of the signal lines 7a and 7b can be narrowed and the dielectric substrate 5 can be downsized.

For example, the lead 4 is formed of 42 alloy, 50 alloy, or Kovar. 50 alloy is also known as 50% Ni—Fe and has a rate of thermal expansion of 9.9 ppm/K. 42 alloy is also known as 42% Ni—Fe and has a rate of thermal expansion of 5 ppm/K. When using SPCC as the material of the base body 2, for example, 50 alloy or 42 alloy is used as the material of the lead 4. When using Kovar as the material of the base body 2, for example, Kovar is used as the material of the lead 4.

The material of the lead 4 and the material of the dielectric substrate 5 can be appropriately combined within a range in which the dielectric substrate 5 and the semiconductor laser 1 do not break due to thermal stress. For example, when Kovar or 42 alloy is used as the material of the leads 4a and 4b, a mismatch in rates of thermal expansion can be suppressed by selecting AlN as the material of the dielectric substrate 5. Therefore, thermal stress applied to the dielectric substrate 5 and the semiconductor laser 1 can be reduced and product reliability can be improved. When 50 alloy is used as the material of the leads 4a and 4b, a mismatch in rates of thermal expansion can be suppressed by selecting Al₂O₃ as the material of the dielectric substrate 5.

### Sixth Embodiment

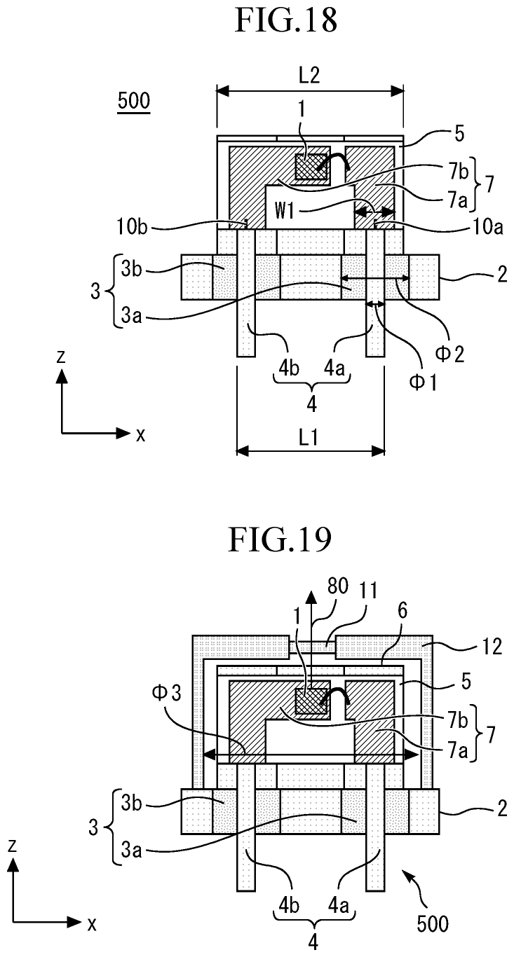

FIG. 17 is a plan view of a semiconductor device 500 according to a sixth embodiment. FIG. 18 is a sectional view of the semiconductor device 500 according to the sixth embodiment. In the semiconductor device 500, a diameter ϕ2 of the sealing bodies 3a and 3b is 0.95 mm and a diameter ϕ1 of the leads 4a and 4b is 0.43 mm. In addition, a distance L1 between centers of the leads 4a and 4b in a plan view is 2 mm. Furthermore, a thickness T1 of the dielectric substrate 5 is 0.2 mm, a material thereof is AlN, and relative permittivity thereof is approximately 9. In addition, a thickness of the signal lines 7a and 7b formed on the dielectric substrate 5 is assumed to be 0.5 μm. Furthermore, a thickness T2 of the semiconductor laser 1 is assumed to be 0.1 mm or less.

A differential impedance of a drive circuit for a semiconductor laser to be driven by a differential signal is often set to 50 Ω. Therefore, by setting a differential impedance of the signal lines 7a and 7b formed on the dielectric substrate 5 to a value close to 50 Ω, high-quality electric signals can be transmitted to the semiconductor laser 1. In the present embodiment, when the differential impedance of the signal lines 7a and 7b is adjusted to 40 Ω or higher, the line width W1 of the signal lines 7a and 7b falls below 1 mm. Accordingly, a length L2 of the dielectric substrate 5 in the x-axis direction can be designed to less than 3 mm. Note that the differential impedance of the signal lines 7a and 7b may be 50 Ω which is an optimal value. As described above, in the present embodiment, the differential impedance of the pair of signal lines 7a and 7b can be set to 40 Ω or higher and the length L2 of the dielectric substrate 5 in the direction along the first face of the base body 2 can be set to less than 3 mm.

Note that, in comparative examples in which the sealing body 3 is not inserted to directly below the rear surface conductor 8 such as the comparative example shown in FIG. 5, the thickness T1 of the dielectric substrate 5 must be set to around 0.48 mm in order to adjust the distance between the lead 4 and the signal line 7 to more or less the same as in the semiconductor device 500. This is a thickness that is comparable to a radius of the sealing body 3. In this case, in order to adjust the characteristic impedance of the signal lines 7a and 7b to more or less the same as in the semiconductor device 500, the line width of the signal lines 7a and 7b must be set to 1.7 mm or more. At this point, the length L2 of the dielectric substrate 5 in the x-axis direction is at least 3.4 mm or more.

FIG. 19 is a sectional view showing a state where a cap 12 has been attached to the semiconductor device 500 according to the sixth embodiment. FIG. 19 shows an example of a completed form of TO-CAN. The cap 12 is provided with a glass opening 11 which transmits laser light emitted by the semiconductor laser 1. The cap 12 hermetically seals the package. Accordingly, a deterioration of quality due to the semiconductor laser 1 being exposed to outside air can be prevented.

Generally, an inner diameter ϕ3 of the cap 12 which is distributed at low cost is approximately 3 mm. In the semiconductor device 800b according to the comparative example, the length L2 of the dielectric substrate 5 is at least 3.4 mm or more. Therefore, the inexpensive cap 12 with an inner diameter of around 3 mm cannot be applied. In contrast, in the present embodiment, the length L2 of the dielectric substrate 5 can be designed to less than 3 mm. Therefore, the inexpensive cap 12 can be readily applied.

### Seventh Embodiment

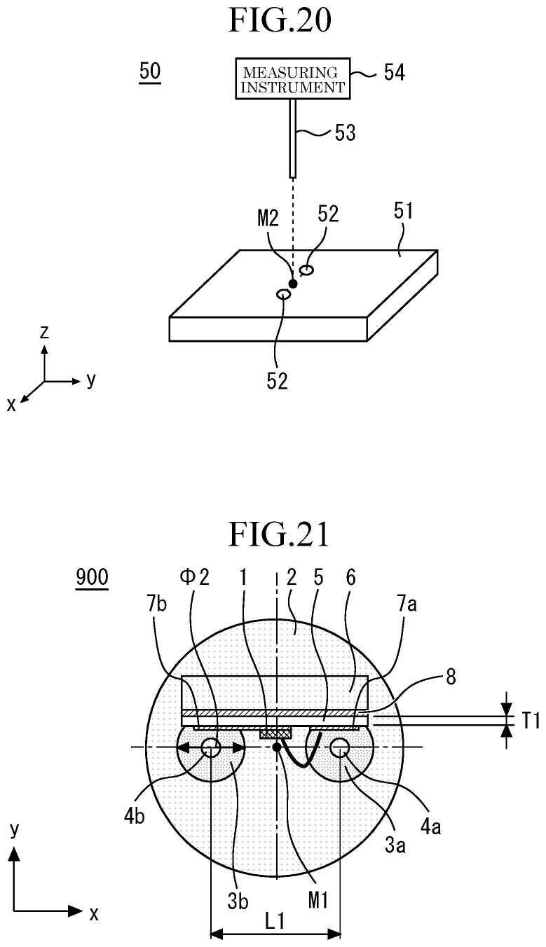

FIG. 20 is a perspective view of a measurement system 50 according to a seventh embodiment. The measurement system 50 measures electrical and optical characteristics of a TO-CAN package for a semiconductor laser. The measurement system 50 includes an energizing jig 51, an optical fiber 53, and a measuring instrument 54. The energizing jig 51 has a lead insertion hole 52 into which the lead 4 of the TO-CAN package is to be inserted and which is used to energize the semiconductor laser 1. In addition, the optical fiber 53 introduces laser light emitted by the semiconductor laser 1 into the measuring instrument 54. The measuring instrument 54 measures various electrical and optical characteristics of the laser light introduced from the optical fiber 53.

A position of the optical fiber 53 on an xy plane coincides with a midpoint M2 of a line segment which connects centers of two lead insertion holes 52. In previously-popular low-speed TO-CAN products with a transmission rate of around 1 Gbps, many products were configured so as to position an emission point of a semiconductor laser in a plan view at a center point of a line segment connecting centers of two leads. Therefore, the measurement system 50 often adopts a configuration such as that shown in FIG. 20.

FIG. 21 is a plan view of a semiconductor device 900 according to a comparative example of the seventh embodiment. In the semiconductor device 900, the sealing body 3 is not inserted toward a side of the conductor block 6 beyond a face where the rear surface conductor 8 and the conductor block 6 come into contact with each other in the y-axis direction. In this case, the face where the rear surface conductor 8 and the conductor block 6 come into contact with each other is separated by at least approximately 0.48 mm in the y-axis direction from the line segment connecting centers of the two leads 4a and 4b. This is a distance that is comparable to a radius of the sealing body 3. In the semiconductor device 900 according to the comparative example, it is assumed that the thickness T1 of the dielectric substrate 5 is reduced to around 0.2 mm which is similar to that in the sixth embodiment in order to reduce an area of the dielectric substrate 5. In this manner, in the semiconductor device 900 according to the comparative example, a position of an emission point of the semiconductor laser 1 on the xy plane deviates in the +y direction from the line segment connecting centers of the leads 4a and 4b.

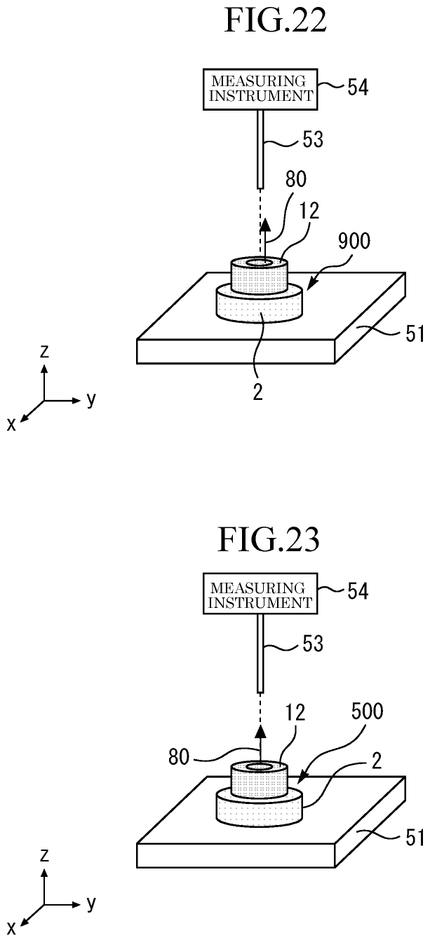

FIG. 22 is a perspective view showing a state where the semiconductor device 900 according to the comparative example has been attached to the energizing jig 51. In this case, a main light beam 80 of the laser light does not coincide with an optical axis of the optical fiber 53. Therefore, an amount of light introduced to the optical fiber 53 is insufficient. Accordingly, measurement accuracy of electrical and optical characteristics may decline.

FIG. 23 is a perspective view showing a state where the semiconductor device 500 according to the sixth embodiment has been attached to the energizing jig 51. As shown in FIG. 17, in the semiconductor device 500, the midpoint M1 of the line segment connecting centers of the pair of leads 4a and 4b and the emission point of the semiconductor laser 1 overlap with each other as viewed from a direction in which the pair of leads 4a and 4b extends. In other words, the emission point of the semiconductor laser 1 is positioned at the midpoint M1 of the line segment connecting centers of the leads 4a and 4b on the xy plane.

In this case, the main light beam 80 of the laser light coincides with the optical axis of the optical fiber 53. Therefore, the laser light can be introduced to the optical fiber 53 in an efficient manner. Accordingly, ideal measurement of electrical and optical characteristics can be realized.

Note that the technical features described in the above embodiments may be combined as appropriate.

### REFERENCE SIGNS LIST

1 semiconductor laser, 2 base body, 3, 3a, 3b sealing body, 4, 4a, 4b lead, 5 dielectric substrate, 6, 6a conductor block, 7, 7a, 7b Signal line, 8 rear surface conductor, 9a, 9b bonding material, 10a, 10b wire, 11 glass opening, 12 cap, 41 upper end face, 50 measurement system, 51 energizing jig, 52 lead insertion hole, 53 optical fiber, 54 measuring instrument, 80 main light beam, 100, 100a, 200, 300, 400, 500, 800a, 800b semiconductor device, 805b dielectric substrate, 806 conductor block, 900 semiconductor device

1. A semiconductor device, comprising:
a base body which has a first face and a second face on an opposite side to the first face and in which a through hole penetrating from the first face to the second face is formed;
a lead which passes through the through hole and which extends to a side of the first face of the base body;
a sealing body which fills a space between the lead and a side surface of the base body forming the through hole;
a dielectric substrate which has a first main surface being provided in a state of being erected with respect to the first face of the base body and a second main surface being a face on an opposite side to the first main surface and being provided in a state of being erected with respect to the first face of the base body;
a semiconductor laser which is provided on a side of the first main surface of the dielectric substrate;
a signal line which is provided on the first main surface of the dielectric substrate and which is electrically connected to the semiconductor laser;
a connecting member which electrically connects the signal line and the lead to each other; and
a rear surface conductor which is provided on the second main surface of the dielectric substrate, wherein
the sealing body is provided directly below the rear surface conductor as viewed from a direction perpendicular to the first face,
the sealing body is provided in a region on an opposite side to the dielectric substrate with respect to the rear surface conductor as viewed from the direction perpendicular to the first face, and
the connecting member is a bonding material.

2. (canceled)

3. A semiconductor device, comprising:
a base body which has a first face and a second face on an opposite side to the first face and in which a through hole penetrating from the first face to the second face is formed;
a lead which passes through the through hole and which extends to a side of the first face of the base body;
a sealing body which fills a space between the lead and a side surface of the base body forming the through hole;
a dielectric substrate which has a first main surface being provided in a state of being erected with respect to the first face of the base body and a second main surface being a face on an opposite side to the first main surface and being provided in a state of being erected with respect to the first face of the base body;
a semiconductor laser which is provided on a side of the first main surface of the di electric substrate;
a signal line which is provided on the first main surface of the dielectric substrate and which is electrically connected to the semiconductor laser;
a connecting member which electrically connects the signal line and the lead to each other;
a rear surface conductor which is provided on the second main surface of the dielectric substrate, and
a conductor block which holds the dielectric substrate via the rear surface conductor on the side of the first face of the base body, wherein
the sealing body is provided directly below the rear surface conductor as viewed from a direction perpendicular to the first face, and
the rear surface conductor has
a contact portion with the conductor block, the contact portion being provided in a portion which overlaps with the semiconductor laser as viewed from a direction perpendicular to the first main surface of the dielectric substrate, and
a separated portion which is provided on at least one side of the contact portion in a direction along the first face of the base body and which is separated from the conductor block.

4. The semiconductor device according to claim 3, wherein the sealing body protrudes between the separated portion and the conductor block as viewed from the direction perpendicular to the first face of the base body.

5. The semiconductor device according to claim 1, wherein a distance between the first face of the base body and the dielectric substrate in the direction perpendicular to the first face of the base body is greater than a distance between the first face of the base body and an end on a side of the dielectric substrate of the lead in the direction perpendicular to the first face of the base body.

6.-7. (canceled)

8. The semiconductor device according to claim 1, wherein
the lead and the signal line oppose each other in a direction perpendicular to the first main surface of the dielectric substrate,
a portion opposing the signal line among the lead and the signal line are electrically connected to each other by the connecting member, and
the connecting member is a bonding material.

9. The semiconductor device according to claim 1, further comprising:
a pair of the leads which respectively pass through a pair of the through holes formed in the base body and which extend to the side of the first face of the base body; and
a pair of the signal lines which are electrically connected to the semiconductor laser and which transmit a differential signal from the pair of leads to the semiconductor laser.

10. The semiconductor device according to claim 9, wherein a differential impedance of the pair of signal lines is 40 Ω or more.

11. The semiconductor device according to claim 9, wherein a length of the dielectric substrate in a direction along the first face of the base body is less than 3 mm.

12. A semiconductor device, comprising:
a base body which has a first face and a second face on an opposite side to the first face and in which a pair of through holes penetrating from the first face to the second face are formed;
a pair of leads which respectively pass through the pair of through holes and which extend to a side of the first face of the base body;
a pair of sealing bodies each filling a space between the lead and a side surface of the base body forming the through hole;
a dielectric substrate which has a first main surface being provided in a state of being erected with respect to the first face of the base body and a second main surface being a face on an opposite side to the first main surface and being provided in a state of being erected with respect to the first face of the base body;
a semiconductor laser which is provided on a side of the first main surface of the dielectric substrate;
a pair of signal lines which are provided on the first main surface of the dielectric substrate, electrically connected to the semiconductor laser and transmit a differential signal from the pair of leads to the semiconductor laser;
a pair of connecting members each electrically connecting the signal line and the lead to each other; and
a rear surface conductor which is provided on the second main surface of the dielectric substrate, wherein
the pair of sealing bodies are provided directly below the rear surface conductor as viewed from a direction perpendicular to the first face, and
a midpoint of a line segment connecting centers of the pair of leads and an emission point of the semiconductor laser overlap with each other as viewed from a direction in which the pair of leads extends.

13. The semiconductor device according to claim 1, wherein the dielectric substrate is formed of alumina, aluminum nitride, or silicon carbide.

14. The semiconductor device according to claim 3, wherein the conductor block is formed of SPCC, Kovar, or copper-tungsten.

15. The semiconductor device according to claim 3, wherein the base body and the conductor block are formed of SPCC and are integrated.

16. The semiconductor device according to claim 3, wherein the base body and the conductor block are formed of Kovar and are integrated.

17. The semiconductor device according to claim 1, wherein the lead is formed of 42 alloy, 50 alloy, or Kovar.

18. The semiconductor device according to claim 3, wherein
the connecting member is a wire,
the dielectric substrate is formed of aluminum nitride, and the conductor block is formed of copper-tungsten.
